(19) United States
(12) Patent Application Publication
(10) Pub. No.: US 2009/0152590 A1
(43) Pub. Date: Jun. 18, 2009

(54) METHOD AND STRUCTURE FOR SEMICONDUCTOR DEVICES WITH SILICON-GERMANIUM DEPOSITS

(75) Inventors: Thomas N. Adam, Poughkeepsie, NY (US); Linda Black, Wappingers Falls, NY (US); Huajie Chen, Danbury, CT (US); Dureseti Chidambarrao, Weston, CT (US); Robert E. Davis, Fishkill, NY (US); Judson R. Holt, Wappingers Falls, NY (US); Randolph F. Knarr, Putnam Valley, NY (US); Christian Lavoie, Pleasantville, NY (US); Robert J. Purtell, West Jordan, UT (US); Dominic J. Schepis, Wappingers Falls, NY (US)

Correspondence Address: CANTOR COLBURN LLP - IBM FISHKILL, 20 Church Street, 22nd Floor, Hartford, CT, 06103, US

(73) Assignees: INTERNATIONAL BUSINESS MACHINES CORPORATION, Armonk, NY (US); ADVANCED MICRO DEVICES, INC. (AMD), Sunnyvale, CA (US)

(21) Appl. No.: 11/955,488

(22) Filed: Dec. 13, 2007

(51) Int. Cl. H01L 29/78; H01L 21/336

(52) U.S. Cl. 257/192; 438/285; 257/E21.409; 257/E29.255

(57) ABSTRACT

A method of forming a semiconductor device including forming a second deposit of silicon-germanium on a first deposit of silicon-germanium, the first deposit formed in a conduction terminal region of a substrate of the semiconductor device and having a first percentage of germanium, and the second deposit having a second percentage of germanium that is less than the first percentage and supports forming a silicide deposit on the second deposit. A structure is also provided.

### BACKGROUND OF THE INVENTION

1. Field of the Invention

This invention relates generally to semiconductor device fabrication, and particularly to a method and structure for semiconductor devices with silicon-germanium deposits.

2. Description of Background

Existing techniques for performance enhancement of p-type field effect transistor devices (“PFETs”) have focused on depositing or embedding silicon-germanium (SiGe) in the source/drain regions of such devices. The embedded SiGe (“eSiGe”) causes stress in the silicon (Si) channel between these regions due to atomic-level structural differences between Si and SiGe, which results in improved device operation. To overcome complexities encountered in forming typical low-resistance electrical-contact materials (known as silicides) on the added eSiGe layer, a layer of Si (or a “Si cap”) has been deposited on top of the eSiGe layer first, since silicide formation on Si is usually less complex than on SiGe.

However, it may be desirable to further improve the manufacturability of such devices through the ability to fabricate the performance-enhancing embedded layer and the silicide-formation facilitating cap layer at the same or similar production parameters, such as temperature and pressure. Furthermore, it may be desirable to further improve the performance of such devices through the ability to minimize or eliminate the decrease of the performance-enhancing stress resulting from the combination of the embedded layer and the cap layer. Additionally, when such devices are fabricated by depositing the embedded layer and cap layer first and then implanting other materials into the base or substrate material by diffusing them through these layers, it may be desirable to further improve manufacturability and performance through the ability to obtain the same or similar diffusion rates of materials implanted through these layers.

### SUMMARY OF THE INVENTION

A method and structure for semiconductor devices with silicon-germanium deposits is provided. One method includes forming a second deposit of silicon-germanium on a first deposit of silicon-germanium, where the first deposit is formed in a conduction terminal region of the substrate of the semiconductor device and includes a first percentage of germanium, and the second deposit includes a second percentage of germanium that is less than the first percentage and supports forming a silicide deposit on the second deposit.

Another method includes forming a first deposit of silicon-germanium in a recess formed in a conduction terminal region of the substrate of the semiconductor device, where the first deposit includes a first percentage of germanium, and forming a second deposit of silicon-germanium on the first deposit, where the second deposit includes a second percentage of germanium that is less than the first percentage and supports forming a silicide deposit on the second deposit. A structure is also provided corresponding to the methods.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIGS. 1A-1D illustrate examples of various stages of fabrication of a structure for semiconductor devices with silicon-germanium deposits.

FIG. 2 illustrates one example of a method for semiconductor devices with silicon-germanium deposits.

FIG. 3 illustrates another example of a method for semiconductor devices with silicon-germanium deposits.

The detailed description explains the preferred embodiments of the invention, together with advantages and features, by way of example with reference to the drawings.

### DETAILED DESCRIPTION OF THE INVENTION

According to exemplary embodiments of the invention described herein, a method and structure for semiconductor devices with silicon-germanium deposits is provided that, among other aspects, facilitates silicide-formation, manufacturability (e.g., quality, quantity, cost, etc.), and performance. For example, improved manufacturability is provided through the ability to fabricate a performance-enhancing embedded layer and a silicide-formation facilitating cap layer in such devices at the same or similar production parameters. Improved performance is provided through the ability to minimize or eliminate the decrease of performance-enhancing stress in such devices resulting from the combination of the embedded layer and the cap layer. Improved manufacturability and performance are further provided through the ability to obtain the same or similar diffusion rates of dopant materials through the embedded layer and the cap layer of such devices.

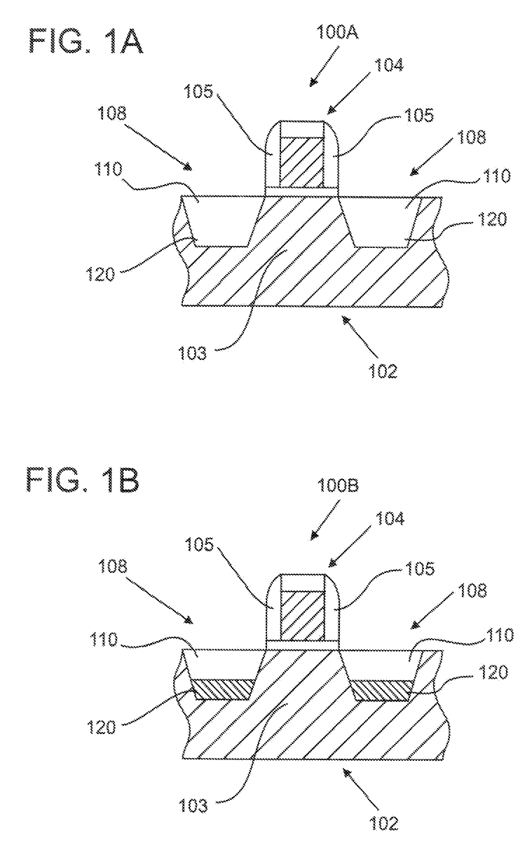

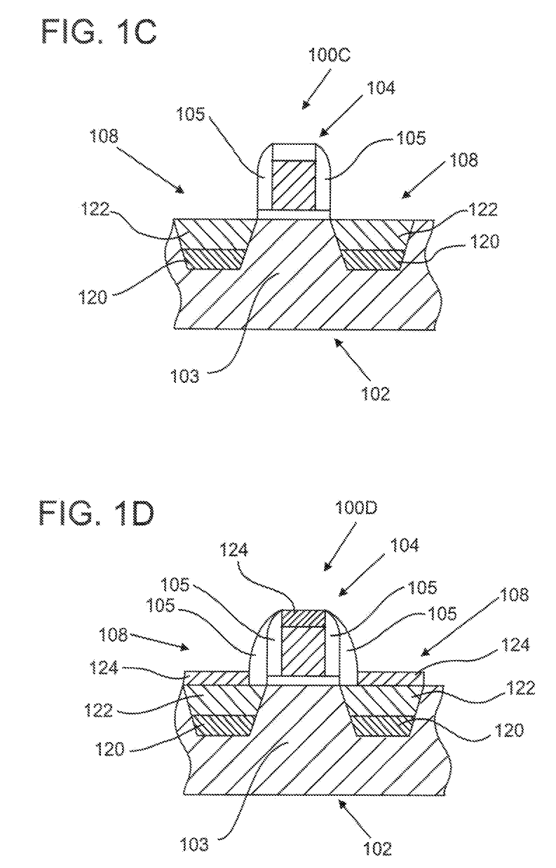

Turning now to the drawings in greater detail, wherein like reference numerals indicate like elements, it will be seen that in FIGS. 1A-1D examples are illustrated of various stages of fabrication of a structure 100 for semiconductor devices with silicon-germanium deposits. FIG. 1A illustrates an example of a structure of a semiconductor device 100A, such as a field-effect transistor (FET), in one stage of fabrication. The exemplary device 100A includes a base or substrate 102, which may be formed of silicon (Si), silicon-on-insulator (SOI), or one or more other semiconductor materials. The device 100A also includes a conduction or channel region 103, a control or gate region 104, conduction terminal or source/drain regions 108, and various insulators or spacers 105 that insulate the gate region 104 from other regions of the device 100A. Recesses or trenches 110 are formed in the source/drain regions 108 of the device 100A for the deposition of other fabrication materials.

FIG. 1B illustrates an example of the structure of the semiconductor device 100B in another stage of fabrication. In this example, the recesses 110 contain at least a partial deposit (or layer) of semiconductor material 120, such as silicon-germanium (SiGe) of some proportionality. In some exemplary embodiments, this first deposit of SiGe 120 has a germanium (Ge) content of about 15% to about 35% with a corresponding Si content of about 85% to about 65%.

As shown in FIG. 1C, which illustrates the semiconductor device 100C in another stage of fabrication, the first deposit is an embedded deposit of, for example, SiGe (“eSiGe”) between the substrate material 102 and a second deposit (or layer) 122. The second deposit of semiconductor material 122 at least partially fills the recesses 110 on top of the first deposit 120 and is also SiGe of some proportionality (e.g., different from that of the first deposit 120). For example, in some embodiments the second deposit 122 of silicon-germanium has a germanium content of about 5% to about 25% with a corresponding silicon content of about 95% to about 75%.

FIG. 1D illustrates an example of the structure of the semiconductor device 100D in another stage of fabrication. In this example, a silicide deposit (or layer) 124 is formed on the second deposit 122 to, for example, provide low resistance electrical contacts to the gate and conduction terminal regions 104, 108. The silicide deposit 124 may be one or more of various materials, such as cobalt silicide (CoSi₂), nickel silicide (NiSi), or titanium silicide (TiSi₂).

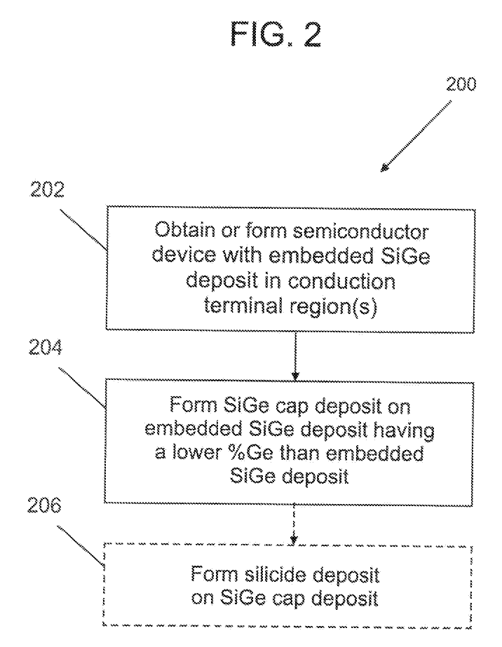

The above-described exemplary semiconductor structure 100 can be provided, for example, according to the following exemplary methods. FIG. 2 illustrates one example of a method 200 for semiconductor devices with silicon-germanium deposits. As shown in block 202, a semiconductor device with SiGe embedded in one or more conduction terminal regions is obtained or formed (e.g., device structure 100B). Such device 100B may, for example, be a p-type field-effect transistor (PFET) with a Si substrate 102 in which a SiGe deposit 120 has been formed in the source and drain regions 108 to obtain performance enhancing stress in the channel region 103 for increased carrier mobility. In some embodiments, the SiGe deposit 120 may be reduced through etching, such as reactive ion etching (RIE), to provide a portion of the recesses 110 for additional deposits.

As then shown in block 204, a SiGe cap deposit 122 is formed (e.g., by epitaxial growth) on the embedded SiGe deposit 120 of the semiconductor device (e.g., device structure 100C). This SiGe cap layer 122 may have a lower percentage of Ge than the eSiGe layer. Furthermore, in some embodiments, the percentage of Ge in the SiGe cap layer 122 may be a value that supports a silicide deposit formation thereupon at a desired resistivity, such as about 20 micro-ohm-centimeters or less. For example, in some embodiments, a SiGe cap layer with about 10% Ge can support a silicide formation with a resistivity of about 20 micro-ohm-centimeters or less. Furthermore, a SiGe cap layer with too high of a Ge percentage, for example greater than about 25% in some instances, generally does not support a silicide formation thereon (e.g., the silicide may diffuse through it instead, thus causing unacceptable device performance).

When an eSiGe layer is used to create performance enhancing stress in a device conduction channel, for example as described above, it has been found that the deposit of a SiGe cap layer having a lower percentage of Ge can cause a decrease in this desirable stress. Therefore, the percentage of Ge in the SiGe cap layer 122 may further be determined as a value that also causes a minimal decrease in that stress as a result of forming the SiGe cap layer 122 on the eSiGe layer 120, which in some embodiments may be, at most, about a 10% decrease.

In some embodiments, an additional processing operation such as shown in block 206 may be included in the method 200 in which a silicide deposit 124 is formed on the SiGe cap deposit 122 to, for example, provide low resistance electrical contacts to the device regions 104, 108. This silicide deposit 124 may have a resistivity of about 20 micro-ohm-centimeters or less in accordance with some embodiments.

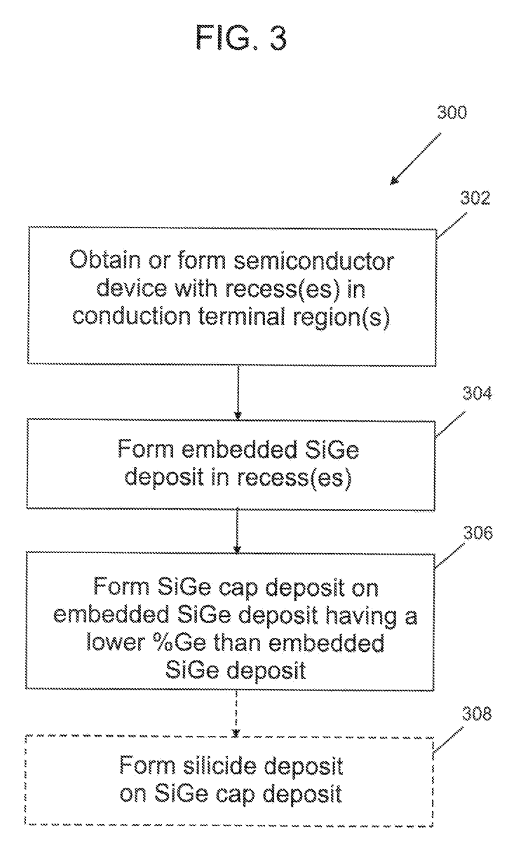

FIG. 3 illustrates another example of a method 300 for semiconductor devices with silicon-germanium deposits. As shown in block 302, a semiconductor device with recesses in one or more source/drain regions is obtained or formed (e.g., device structure 100A). Such device 100A may be, for example, a PFET with a Si substrate 102 in which recesses 110 have been etched in the source and drain regions 108 (e.g., by RIE). In some embodiments, these recesses 110 may be etched into the substrate 102 a part of the processing operation shown in block 302.

As shown in block 304, a SiGe deposit 120 is formed in the recesses 110 in a manner that may, for example, leave a portion of the recesses 110 open for a second deposit (e.g., as in structure 100B). For example, this deposit may provide an embedded SiGe layer 120 in the source and drain regions 108 to obtain performance enhancing stress in the channel region 103 for increased carrier mobility. In block 306, a SiGe cap deposit 122 is formed (e.g., by epitaxial growth) on the embedded SiGe deposit 120 of the semiconductor device (e.g., device structure 100C). The exemplary details and variations of block 306 are the same or substantially similar to those described above for block 204 of FIG. 2.

In some embodiments, the forming of the eSiGe deposit 120 in block 304 and of the SiGe cap deposit 122 in step 306 may be performed by a continuous deposition of SiGe in which the percentage of Ge is varied from a first percentage for the eSiGe deposit 120 to a second percentage for the SiGe cap deposit 122. Such a continuous deposition may be performed under the same or similar fabrication parameters, such as temperature, pressure, atmosphere, etc. Thus, the use of a SiGe cap layer 122 on the eSiGe layer 120 provides for improved manufacturability.

In some device fabrication processes, the eSiGe deposit 120 and the SiGe cap deposit 122 may be formed in the substrate 102 before dopants are implanted in the substrate 102 to further form the device (e.g., in so-called “early eSiGe” processes). In such cases, the difference in the diffusion rates of the dopant (e.g., boron (B) or aluminum (Al) in the case of PFETs) can affect both the manufacturability and performance of the device. Therefore, the percentage of Ge in the eSiGe layer 120 may be determined as a value that provides a diffusion rate in that layer 120 that is at least some fraction of the diffusion rate of the dopant in the SiGe cap layer 122 (which generally will be faster if it has a lower percentage of Ge). For example, in some embodiments, the value is determined to provide a diffusion rate in the eSiGe layer 120 that is at least about 40% of the diffusion rate in the SiGe cap layer 122 (which, in other words, would provide for a diffusion rate in the cap layer 122 that is at most about 2.5 times faster than the rate provided in the embedded layer 120).

In some embodiments, a silicide deposit 124 is formed on the SiGe cap deposit 122, as shown in block 308. The exemplary details and variations of this operation in block 308 are the same or substantially similar to those described above for block 206.

The flow diagrams depicted herein are just examples. There may be many variations to these diagrams or the blocks (or operations) described therein without departing from the spirit of embodiments of the invention. For instance, the blocks may be performed in a differing order, or blocks may be added, deleted or modified. All of these variations are considered a part of the claimed invention.

The methods described above are used in the fabrication of integrated circuit chips. The resulting integrated chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has surface interconnections and/or buried connections). In any case, the chip is then integrated with other chips, discrete circuit elements, and/or other signal processing devices as part of either (a) any intermediate product, such as a motherboard, or (b) an end product. The end product can be any product that includes integrated circuit chips, ranging from toys and other low-end applications to advanced computer products having a display, a keyboard or other input device, and a central processor.

While exemplary embodiments of the invention have been described, it will be understood that those skilled in the art, both now and in the future, may make various improvements and enhancements which fall within the scope of the claims which follow. These claims should be construed to maintain the proper protection for the invention first described.

What is claimed is:

1. A method of forming a semiconductor device, the method comprising:
forming a second deposit of silicon-germanium on a first deposit of silicon-germanium, the first deposit formed in a conduction terminal region of a substrate of the semiconductor device and having a first percentage of germanium; and
the second deposit having a second percentage of germanium that is less than the first percentage and supports forming a silicide deposit on the second deposit.

2. The method of claim 1, wherein the second percentage of germanium supports forming a silicide deposit on the second deposit having a resistivity of about 20 micro-ohm-centimeters or less.

3. The method of claim 1, wherein the first percentage of germanium supports a first diffusion rate of a dopant in the first deposit that is at least about 40% of a second diffusion rate of the dopant in the second deposit that is supported by the second percentage.

4. The method of claim 1, wherein the first deposit creates an initial performance-enhancing stress in a conduction channel of the substrate and the second percentage is selected so as to limit a change in the initial stress as a result of forming the second deposit to about a 10% or less decrease in the initial stress.

5. The method of claim 1, wherein the semiconductor device is a p-type field effect transistor (PFET) and the conduction terminal region is a source or drain region.

6. The method of claim 5, wherein the PFET substrate is silicon, the first percentage of germanium is in the range of about 15% to about 35%, and the second percentage of germanium is in the range of about 5% to about 25%.

7. The method of claim 1, further comprising forming the silicide deposit on the second deposit, the silicide deposit having a resistivity of about 20 micro-ohm-centimeters or less.

8. A method of forming a semiconductor device, the method comprising:
forming a first deposit of silicon-germanium in a recess formed in a conduction terminal region of a substrate of the semiconductor device, the first deposit having a first percentage of germanium; and
forming a second deposit of silicon-germanium on the first deposit, the second deposit having a second percentage of germanium that is less than the first percentage and supports forming a silicide deposit on the second deposit.

9. The method of claim 8, wherein forming the first deposit and forming the second deposit is performed by a continuous deposition of silicon-germanium beginning with the first percentage of germanium and completed with the second percentage of germanium under substantially similar fabrication parameters.

10. The method of claim 8, wherein the second percentage of germanium supports forming a silicide deposit on the second deposit having a resistivity of about 20 micro-ohm-centimeters or less.

11. The method of claim 8, wherein the first percentage of germanium supports a first diffusion rate of a dopant in the first deposit that is at least about 40% of a second diffusion rate of the dopant in the second deposit that is supported by the second percentage.

12. The method of claim 8, wherein the first deposit creates an initial performance-enhancing stress in a conduction channel of the substrate of the semiconductor device and the second percentage is selected so as to limit a change in the initial stress as a result of forming the second deposit to about a 10% or less decrease in the initial stress.

13. The method of claim 8, further comprising forming the silicide deposit on the second deposit, the silicide deposit having a resistivity of about 20 micro-ohm-centimeters or less, and wherein:
the semiconductor device is a p-type field effect transistor (PFET) having a silicon substrate;
the conduction terminal region is a source or drain region;
the first percentage of germanium is about 20%; and
the second percentage of germanium is about 10%.

14. A semiconductor device structure, comprising:
a substrate having a recess in a conduction terminal region thereof;
a first deposit of silicon-germanium in the recess, the first deposit having a first percentage of germanium; and
a second deposit of silicon-germanium on the first deposit, the second deposit having a second percentage of germanium that is less than the first percentage and supports forming a silicide deposit on the second deposit.

15. The structure of claim 14, wherein the second percentage of germanium supports forming a silicide deposit on the second deposit having a resistivity of about 20 micro-ohm-centimeters or less.

16. The structure of claim 14, wherein the first percentage of germanium supports a first diffusion rate of a dopant in the first deposit that is at least about 40% of a second diffusion rate of the dopant in the second deposit that is supported by the second percentage.

17. The structure of claim 14, wherein the first deposit creates an initial performance-enhancing stress in a conduction channel of the semiconductor device and the second percentage is selected so as to limit a change in the initial stress as a result of forming the second deposit to about a 10% or less decrease in the initial stress.

18. The structure of claim 14, wherein the semiconductor device is a p-type field effect transistor (PFET) and the conduction terminal region is a source or drain region.

19. The structure of claim 18, wherein the PFET substrate is silicon, the first percentage of germanium is in the range of about 15% to about 35%, and the second percentage of germanium is in the range of about 5% to about 25%.

20. The structure of claim 14, further comprising the silicide deposit formed on the second deposit with a resistivity of about 20 micro-ohm-centimeters or less.
